(19) United States
(12) Patent Application Publication
(10) Pub. No.: US 2005/0230598 A1
(43) Pub. Date: Oct. 20, 2005

(54) Systems and methods for detecting and translating sunlight exposure data

(75) Inventors: Tonia M. Hopkins, Atlanta, GA (US); Charles M. Miller, Alexandria, VA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Tonia M. Hopkins

(21) Appl. No.: 11/020,887

(22) Filed: Dec. 22, 2004

Related U.S. Application Data
(60) Provisional application No. 60/563,260, filed on Apr. 16, 2004.

(51) Int. Cl. H01L 27/00

(52) U.S. Cl. 250/208.1

(57) ABSTRACT

A method for providing sunlight exposure data is provided by detecting and collecting sunlight data for analysis, classification and communication to a user. The sunlight exposure data is communicated to a user in the form of alpha, numeric or graphical elements through a local display component or data cable to a remote device capable of receiving and displaying the data.

### CROSS-REFERENCE TO RELATED APPLICATION

This application claims priority to copending U.S. provisional application entitled, “INTERGRATING SUN METER” having Ser. No. 60/563,260 filed Apr. 16, 2004, which is entirely incorporated herein by reference.

### TECHNICAL FIELD

The present disclosure is generally related to detecting, collecting and analyzing environmental data and, more particularly, is related to a system and method for providing sunlight exposure information in a useful format.

### BACKGROUND

Plants have requirements for adequate sunlight and the actual sun requirements vary among different plant species. Plant nurseries frequently have a grower's tag that describes the exposure requirements of specific plant species. These tags frequently feature an icon that describes the exposure as full sun, partial sun, partial shade, and full shade. One problem then is to determine the sun patterns in a planting area to determine which plant species will be best suited for the planting area. Most gardeners, however, do not have the time or equipment to study the sun patterns of a planting area. Present devices for measuring radiation intensity include that of U.S. Pat. No. 6,114,687 to Sharp et al., which is hereby incorporated by reference.

Thus, a heretofore-unaddressed need exists in the industry to address the aforementioned deficiencies and inadequacies.

### SUMMARY

Briefly described, in architecture, one embodiment of the system, among others, can be implemented as a system for providing sun exposure data, comprising: a photoelectric detector, for receiving sunlight; a sunlight data collector, wherein data corresponding to sunlight received by the photoelectric detector is collected; a sunlight data analyzer, for determining a number of sunlight hours, wherein the number of sunlight hours corresponds to the number of hours that sunlight is received by the photoelectric detector in a day; a sunlight data translator adapted to assign one of a plurality of sunlight exposure classifications corresponding to the number of hours of sunlight received in a day; and a display, adapted to generate an image of one of a plurality of graphical display icons corresponding to the one of the plurality of sunlight exposure classifications.

An embodiment of the present disclosure can also be viewed as providing a method for providing sunlight exposure data, comprising the steps of: detecting sunlight, using a photoelectric device configured to provide an electrical circuit element that responds to sunlight; collecting sunlight data, wherein the sunlight data is collected from the detector; storing the sunlight data, wherein the sunlight data is stored in a memory device; analyzing the sunlight data, to determine a daily sunlight hours value, corresponding to the number of hours of sunlight detected per day; classifying the sunlight data, such that a plurality of ranges of the daily sunlight hours value corresponds to a plurality of sunlight exposure classifications; and displaying the sunlight data.

An embodiment of the present disclosure can also be viewed as providing a system for collecting sun exposure data, comprising: a sunlight detecting means for providing a signal when sunlight is present at a sensor; a sunlight data collecting means for receiving data from the sensor; a sunlight data storing means for accumulating the sunlight data in a memory device; a sunlight data analyzing means for determining a daily sunlight hours value, corresponding to the number of hours of sunlight detected per day; a sunlight data classifying means for determining a classification based on the daily sunlight hours value; and a data displaying means for delivering the classification in the form of a graphical display symbol.

An embodiment of the present disclosure can also be viewed as providing an apparatus for determining average daily light exposure in an outdoor location, comprising: a light data collector, configured to record an amount of time a location receives direct illumination from a light source; and a graphical display adapted to transmit, through graphical images, the amount of time the location receives direct illumination.

An embodiment of the present disclosure can also be viewed as an apparatus for determining sun exposure, comprising, a light collector; logic configured to measure an amount of time in which a luminous intensity threshold is exceeded for the light collector over a predetermined period of time; and logic for generating an output indicative of the measure of time.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a block diagram illustrating components of an embodiment as disclosed herein.

FIG. 2 is a block diagram illustrating functional elements of an embodiment of the systems and methods disclosed herein.

FIGS. 3A-3E illustrate exemplary graphical symbols for different classifications of sunlight exposure.

FIG. 4 is a block diagram illustrating an embodiment of a method as disclosed herein.

FIG. 5 is a block diagram illustrating a method of analyzing and classifying sunlight data retained as counter values.

### DETAILED DESCRIPTION

Reference is now made in detail to the description of the embodiments as illustrated in the drawings. While several embodiments are described in connection with these drawings, there is no intent to limit the invention to the embodiment or embodiments disclosed herein. On the contrary, the intent is to cover all alternatives, modifications, and equivalents.

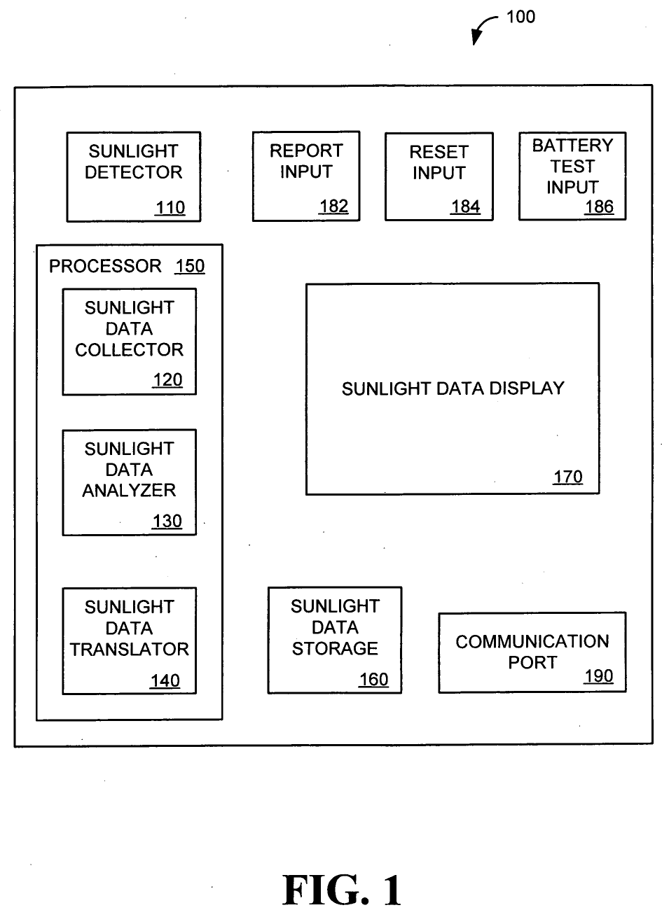

Reference is made to FIG. 1, which is a block diagram illustrating exemplary components of an embodiment as disclosed herein. The system 100 includes a sunlight detector 110, which, in an embodiment is a cadmium sulfide photocell. The sunlight detector 110 produces a change in electrical characteristics under varying light levels such that exposure to a high level of light, such as direct sunlight generates an electrically distinguishable characteristic as found in photoelectric detectors known to one of ordinary skill in the art. Electrically distinguishable characteristics under this disclosure include, but are not limited to, resistance, voltage, current, and impedance. Additionally, photo reactive devices are often very sensitive and require an optical filter (not shown) to produce a stable response.

The detector 110 is communicatively coupled to a sunlight data collector 120, which accumulates data relating to the relative amount of sunlight exposure. For example, in an embodiment, the sunlight data collector 120 may be configured to collect data samples on a regular interval based on some predetermined sampling rate. At each regular interval, the sunlight data collector 120 may increment a total number of samples counter to record the total number of samples. The sunlight data collector 120 may then increment a sunlight present counter if the detector 110 indicates the presence of direct sunlight. In this manner, the sunlight data collector 120 serves to collect data for many consecutive days. The sunlight data may be stored in a sunlight data storage device 160, including but not limited to, for example, non-volatile memory. One of ordinary skill in the art knows or will know that alternate embodiments could utilize light detectors capable of many different photo reactive characteristics.

Also included in an embodiment of the system 100 is a sunlight data analyzer 130 for analyzing the sunlight exposure data to determine the number of hours of sunlight a particular location receives each day. For example, the sunlight data analyzer 130 may use the value in a total number of samples counter, the value in a sunlight present counter, and the sampling rate to determine the number of hours of sunlight exposure the location receives. One of ordinary skill in the art knows or will know that the sunlight data may be collected and analyzed using numerous techniques under the systems and methods disclosed herein.

The system 100 also includes a sunlight data translator 140, for translating the numerical sunlight exposure data into specific classifications or categories, which represent different ranges of exposure on the exposure continuum from no sunlight exposure to full sunlight exposure. An embodiment of the systems and methods herein classifies the sunlight into five different ranges as indicated by the following table:

| Number of Hours of Direct | |
|---|---|
| Sunlight | Classification |
| 0-3 | Shade |
| 3-4.5 | Partial Shade |
| 4.5-6 | Partial Sun |
| >6 | Sun |

One of ordinary skill in the art knows or will know that the exemplary ranges in the above table are not intended to limit the scope of the disclosure in any way and are merely presented by way of example.

In an embodiment as illustrated in FIG. 1, the functions of the sunlight data collector 120, the sunlight data analyzer 130, and the sunlight data translator 140 may be performed through software or firmware in the context of a processor 150. Additionally, although not shown, the processor 150 may be configured to include hardware for performing the sunlight data storage function 160 as well.

An embodiment of the system 100 also includes a report input 182, allowing the user to cause the system 100 to communicate the results of the sunlight data collection, analysis, and translation. The results of the sunlight data collection, analysis, and translation may be in the form of a numerical value, which represents the number of hours of direct sunlight a location receives each day. Alternatively, the results may be communicated as a categorical classification consistent with, for example, the classifications discussed above. Further, the results may be displayed in a graphical representation, where, for example, graphical symbols represent varying levels of sunlight exposure per day. The results may be communicated to an external device via a communication port 190 to a compatible device. Additionally or in the alternative, the results may be communicated through a local sunlight data display 170. The report input 182 may be an electrical switch or button local to the system or a digital or analog data signal delivered through a communication port 190.

An embodiment of the system 100 also includes a reset input 184, for clearing, erasing, or eliminating previously collected data. Consistent with the report input 182; the reset input 184 may be an electrical switch or button local to the system or a digital or analog data signal delivered through a communication port 190. One use of the reset input 184 is to determine the sunlight exposure corresponding to a different location since failure to eliminate data associated with a previous location would produce inaccuracies in subsequent reporting. An embodiment of the system 100 also includes a battery test input 186, which, when actuated, causes the system 100 to communicate the charge level of a system battery (not shown).

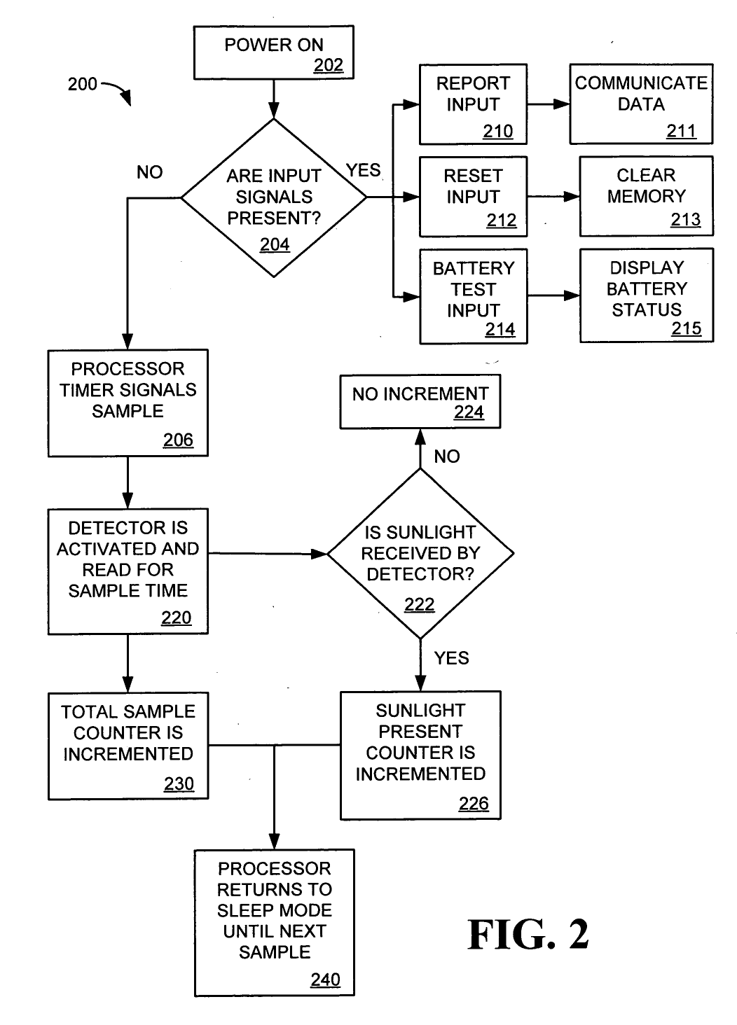

Reference is now made to FIG. 2, a block diagram illustrating functional elements of an embodiment of the systems and methods disclosed herein. The system 200 begins when power is applied 202, either by actuating a power switch (not shown) or installing one or more batteries (not shown). After starting, the system determines if any input signals are present 204. If a report input 210 is present during the startup, then the sunlight exposure data is communicated in, for example, a local display 211. If a reset input 212 is present then all of the previously stored sunlight exposure data is cleared from the memory 213. If a battery test input 214 is present, then the charge level or estimated remaining battery capacity is displayed on, for example, a local display 215. In an alternate embodiment, the report input 210, the reset input 212 and the battery test input 214 and their corresponding functions are available at anytime and not just during the startup.

If no input signals are detected during startup a processor timer signals that a data sample should be taken from the detector 206. The detector is activated from a state of minimal energy consumption and the detector output is determined for the particular sample 220. If sunlight is received by the detector 222, then the sunlight present counter is incremented 226. If the output indicates that the detector is not receiving direct sunlight, then the sunlight present counter is not incremented 224. Whether or not the detector receives sunlight, a total number of samples counter is incremented 230. The processor then returns to a sleep or very low energy consumption mode for the predetermined interval between data samples 240. Although an embodiment of this system 200 uses a processor and selectively increments counters at sample intervals using discrete methods, a continuous time-based system utilizing analog components could also be implemented consistent with the scope and spirit of the disclosure and claims herein.

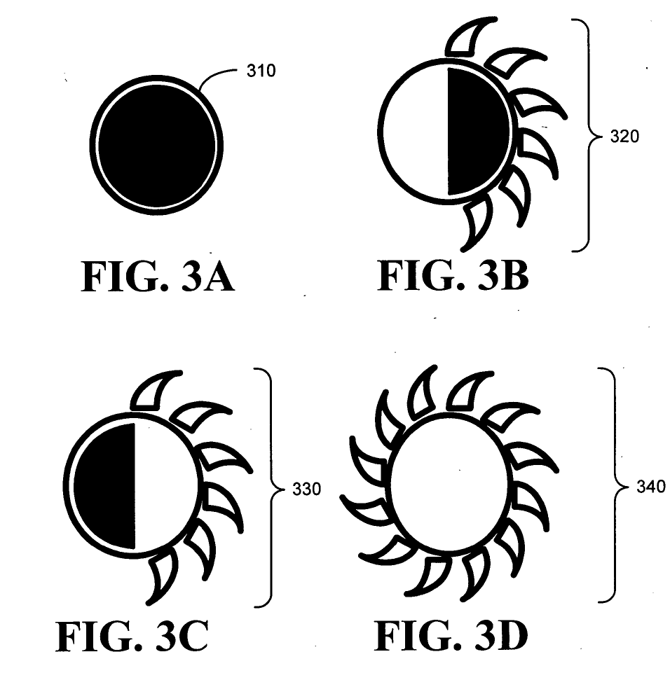

Reference is now made to FIGS. 3A-3D, which illustrate exemplary graphical symbols for different classifications of sunlight exposure. Using the exemplary classifications of the table above, the graphical symbol 310 of FIG. 3A would correspond to a shade classification. Accordingly, the graphical symbols 320, 330, and 340 of FIGS. 3B-3D would correspond to the classifications of partial shade, partial sun, and sun, respectively. The graphical symbols of FIG. 3 are beneficial in several respects. First, they give a quick and easy to analyze indicator of the amount of sunlight exposure a particular location receives. Second, since the graphical symbols are consistent with those used by plant suppliers, the gardening hobbyist and professional alike can have a reliable indicator as to which plant types are suited for specific locations in any season.

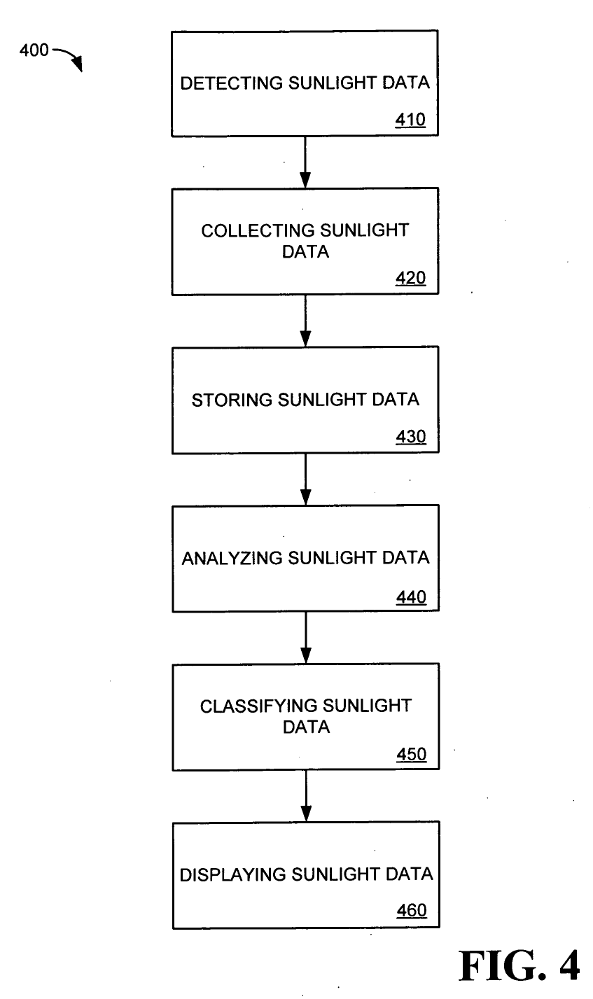

Reference is now made to FIG. 4, which is a block diagram illustrating an embodiment of a method as disclosed herein. The method 400 starts by detecting sunlight data 410 through, for example, a photoelectric sensor optionally configured with a filtering element. The sunlight data is collected 420 through, for example, a data receiving and accumulation device. As discussed above, a processor can be used to perform this function. The collected data is then stored 430 for analysis 440 and later retrieval. The analyzing step 440 includes, for example, determining how many hours per day the location receives direct sunlight at the detector. Classifying sunlight data 450 includes assigning a sunlight exposure classification based on the amount of sunlight received in a day. After the sunlight data is classified 450, the data may be communicated through, for example, a local display 460. As discussed above, specific graphical symbols may be used to communicate the classifications. Alternatively, the sunlight data may be communicated in an alpha-based description and/or a numerical format indicating a sunlight exposure value.

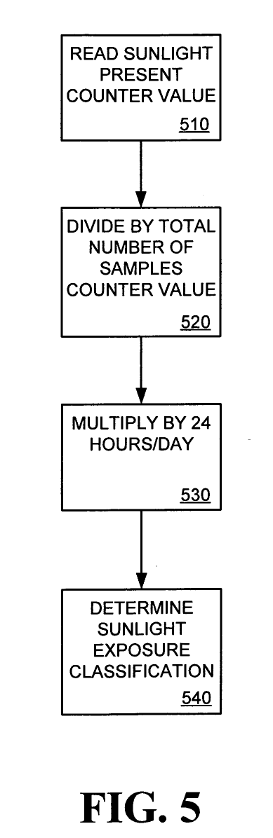

Reference is now made to FIG. 5, which is a block diagram illustrating a method of analyzing and classifying sunlight data retained as counter values. The value from the sunlight present counter is read from, for example, a memory location 510. This value is divided by the value of a total number of samples counter 520. The resulting product is multiplied by 24, based on the number of hours in a day 530. The numerical value is then compared to the ranges associated with different sunlight exposure classifications to determine, for example, which graphical symbol to display 540.

A non limiting embodiment of this disclosure may also be viewed as an apparatus comprising a light collector coupled with logic configured to measure the amount of time in which the luminous intensity is exceeded over a predetermined period of time. For example, the logic provides a threshold for distinguishing between cloud cover and shade generated by shade producers providing less light transmission, such as trees, leaves and structures.

Additionally, logic is provided for generating an output indicative of the measure of time. In one non-limiting function, this logic analyzes the data associated with the measured time and may further classify the data into classifications or categories based on predetermined ranges of exposure. As discussed above, the output can be in the form of an alpha, numeric, or graphical display. Further, the output may be generated on a local display or transmitted to an external device.

Embodiments of the present disclosure can be implemented in hardware, software, firmware, or a combination thereof In the illustrated embodiments, the systems and methods may be implemented in software or firmware that is stored in a memory and that is executed by a suitable instruction execution system. If implemented in hardware, as in an alternative embodiment, the systems and methods can be implemented with any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

Any process descriptions or blocks in flow charts should be understood as representing modules, segments, or portions of code which, include one or more executable instructions for implementing specific logical functions or steps in the process, and alternate implementations are included within the scope of an embodiment of the present disclosure in which functions may be executed out of order from that shown or discussed, including substantially concurrently or in reverse order, depending on the functionality involved, as would be understood by those reasonably skilled in the art of the present disclosure.

Under an embodiment, the sunlight exposure detection and translation programs, which comprise ordered listings of executable instructions for implementing logical functions, can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, propagate, or transport the program for use by or in connection with the instruction execution system, apparatus, or device. The computer readable medium can be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory. In addition, the scope of the present disclosure includes embodying the functionality of the illustrated embodiments of the present disclosure in logic embodied in hardware or software-configured mediums.

It should be emphasized that the above-described embodiments of the present disclosure, particularly, any illustrated embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

1. A system for providing sun exposure data, comprising:
a photoelectric detector, for receiving sunlight;
a sunlight data collector, wherein data corresponding to sunlight received by the photoelectric detector is collected;
a sunlight data analyzer, for determining a number of sunlight hours, wherein the number of sunlight hours corresponds to the number of hours that sunlight is received by the photoelectric detector in a day;
a sunlight data translator adapted to assign one of a plurality of sunlight exposure classifications corresponding to the number of hours of sunlight received in a day; and
a display, adapted to generate an image of one of a plurality of graphical display icons corresponding to the one of the plurality of sunlight exposure classifications.

2. The system of claim 1, wherein the one of the plurality of sunlight exposure classifications is selected from the group of classifications including: shade, partial shade, partial sun, and sun.

3. The system of claim 1, wherein a processor is adapted to perform the functions of the sunlight data collector, the sunlight data analyzer, and the sunlight data translator.

4. The system of claim 3, wherein the processor is adapted to establish a sampling rate, wherein the processor is further adapted to collect sunlight data from the photoelectric detector at a time interval corresponding to the sampling rate.

5. The system of claim 4, wherein the processor increments a total sample counter at each time interval, wherein the processor increments a sunlight counter at each time interval in which the photoelectric detector receives sunlight, and wherein a number of sunlight hours per day value is determined by dividing a value in the total sample counter by a value in the sunlight counter and multiplying by the number of hours per day.

6. The system of claim 5, further comprising a report input device, electrically coupled to the sunlight data collector, wherein actuation of the report input device causes the processor to report the number of sunlight hours per day.

7. The system of claim 6, further comprising a reset input device, electrically coupled to the sunlight data collector, wherein actuation of the reset input device causes the processor to clear all counter values.

8. The system of claim 1, further comprising a battery test input device, electrically coupled to the system, wherein actuation of the battery test input device causes the display to indicate a charge status of a battery.

9. The system of claim 1, wherein the sunlight data is stored in a memory location for accumulation and later retrieval.

10. A method for providing sunlight exposure data, comprising the steps of:
detecting sunlight, using a photoelectric device configured to provide an electrical circuit element that responds to sunlight;
collecting sunlight data, wherein the sunlight data is collected from the detector,
storing the sunlight data, wherein the sunlight data is stored in a memory device;
analyzing the sunlight data, to determine a daily sunlight hours value, corresponding to the number of hours of sunlight detected per day;
classifying the sunlight data, such that a plurality of ranges of the daily sunlight hours value corresponds to a plurality of sunlight exposure classifications; and
displaying the sunlight data.

11. The method of claim 10, further comprising the step of assigning a plurality of graphical display symbols to the plurality of sunlight exposure classifications, such that each of the plurality of classifications corresponds to a specific one of the plurality of graphical display symbols.

12. The method of claim 11, wherein the displaying step comprises displaying the one of the plurality of graphical display symbols which corresponds to the daily sunlight hours value.

13. The method of claim 10, wherein the displaying step is initiated when a report input device is actuated.

14. The method of claim 10, wherein the sunlight data stored in the memory device is cleared when a reset input device is actuated.

15. The method of claim 10, wherein the analyzing, storing, and classifying steps are performed in a processor.

16. The method of claim 10, wherein the collecting step is performed at regular intervals, such that the time between the intervals is determined by a sampling rate.

17. The method of claim 16, wherein the collecting step increments a total sample counter value at each of the regular intervals and wherein the collecting step increments a sunlight present counter value at each of the regular intervals where the photoelectric device indicates the presence of sunlight.

18. The method of claim 17, wherein the analyzing step determines a number of sunlight hours per day value by dividing the sunlight present counter value by the total sample counter value and multiplying the product by 24.

19. A system for collecting sun exposure data, comprising:
a sunlight detecting means for providing a signal when sunlight is present at a sensor;
a sunlight data collecting means for receiving data from the sensor;
a sunlight data storing means for accumulating the sunlight data in a memory device;
a sunlight data analyzing means for determining a daily sunlight hours value, corresponding to the number of hours of sunlight detected per day;
a sunlight data classifying means for determining a classification based on the daily sunlight hours value; and
a data displaying means for delivering the classification in the form of a graphical display symbol.

20. An apparatus for determining average daily light exposure in an outdoor location, comprising:
a light data collector, configured to record an amount of time a location receives direct illumination from a light source; and
a graphical display adapted to transmit, through graphical images, the amount of time the location receives direct illumination.

21. An apparatus for determining sun exposure, comprising,
a light collector;
logic configured to measure an amount of time in which a luminous intensity threshold is exceeded for the light collector over a predetermined period of time; and
logic for generating an output indicative of the measure of time.

22. The apparatus of claim 21, wherein the output is a graphical image.
